(19) United States
(12) Patent Application Publication
(10) Pub. No.: US 2009/0175016 A1
(43) Pub. Date: Jul. 9, 2009

(54) CLIP FOR ATTACHING PANELS

(75) Inventors: Anton Legen, Munchen (DE); Steve Wood, Munchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Munchen (DE)

(21) Appl. No.: 11/969,333

(22) Filed: Jan. 4, 2008

(51) Int. Cl. H05K 1/14; H01R 12/16

(52) U.S. Cl. 361/787; 361/784; 361/790

(57) ABSTRACT

Clip for attaching two outer panels to an intermediate panel, the clip comprising two arm portions each arm portion being configured to apply pressure to one of the outer panels in order to force the panel against a surface of the intermediate panel, and a bridge portion connecting the two arm portions, the bridge portion comprising a central section configured to provide mechanical coupling to the intermediate panel.

### BACKGROUND

Many technical applications use panels or boards, respectively, as carriers of electronic circuits. Such circuit boards generally include conductive pathways formed on a non-conductive substrate, e.g., etched metal sheets laminated onto a ceramic substrate. Circuit boards are often used to mechanically support and electrically connect electronic components mounted either on one or on both sides of the circuit board. Depending on the specific application, the electronic components populating the circuit board can be formed as basic components, e.g., capacitor, resistor or transistor, or as more complex electronic devices, such as integrated circuit devices. The integrated circuit devices may typically include electronic data memories, microprocessors, programmable logic devices, integrated digital and/or analogue circuitries. Examples for electronic data memories include DRAM devices, flash RAM devices, SRAM devices, PCRAM devices, MRAM devices, CBRAM devices, and other volatile and non-volatile memory devices.

Some technical applications use specific panels which are attached to the circuit board in order to form a stack. These panels may serve different purposes such as dissipation of heat, electro-magnetic shielding or mechanical protection of the electronic components mounted on the circuit board or fixing of the circuit board, just to mention some examples. Panels and circuit boards may be attached to each other in order to form an assembly, e.g., a circuit board assembly. The attachment of the panels may be reversible in order to allow a flexible combination of circuit boards and panels.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a perspective view of a clip with a sigma-shaped body according to a first embodiment.

FIG. 2 illustrates a cross-sectional view from top of an assembly including a circuit board having both sides populated with electronic components and two panels attached to the electronic components by the clip of FIG. 1.

FIG. 3 illustrates a side view of the assembly of FIG. 2.

FIG. 4 illustrates a perspective view of a clip with a sigma-shaped body according to a second embodiment.

FIG. 5 illustrates a cross-sectional view from top of an assembly including a circuit board having both sides populated with electronic components and two panels attached to the electronic components by the clip of FIG. 4.

FIG. 6 illustrates a side view of the assembly of FIG. 5.

FIG. 7 illustrates a perspective view of a clip with a sigma-shaped body according to a third embodiment.

FIG. 8 illustrates a cross-sectional view of an assembly including a circuit board having both sides populated with electronic components and two panels attached to the electronic components by a clip according to a fourth embodiment.

FIG. 9 illustrates a cross-sectional view of an assembly including a circuit board having both sides populated with electronic components and two panels attached to the electronic components by a clip according to a fifth embodiment.

FIG. 10 illustrates a cross-sectional top view of an assembly including a double-sided circuit board with a set of four electronic components populating each side of the board and two panels, each panel being attached to one set of electronic components by two clips.

FIG. 11 illustrates a cross-sectional top view of an assembly including a central panel and two circuit boards attached to the panel attached by two clips, each circuit board being populated with a set of four electronic components.

FIG. 12 illustrates a computer device including an assembly with a circuit board and two panels attached thereto by two clips.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Heat dissipating panels such as heat spreaders, heat sinks or the like may be used to dissipate the heat generated by electronic components mounted on a circuit board in order to avoid damage to these devices. These panels may include bodies of heat-conducting materials such as copper or aluminum. The body of a heat dissipating panel generally includes a base plate with a heat receiving contact surface. The shape of the contact surface may be adapted to the shape of the contact area of the corresponding electronic component or circuit board. In order to improve the heat radiation, the panel may include additional structures such as radiating fins or surfaces projecting from the base plate.

To ensure a heat conductance between an electronic component and a heat dissipating panel, the panel may be attached to the circuit board in direct contact with the respective electronic component. However, an adequate thermal transfer may also be achieved by using an intermediate thermo-conductive element arranged between the panel and the electronic component. Alternatively, the panel can also be arranged directly on the surface of the circuit board.

In order to provide a reversible connection between the circuit board and the panels arranged at one or two sides of the circuit board, the panels and the circuit board may be clamped together by one or more clips. These clips may be formed to simultaneously attach a first panel to a first side of a circuit board and a second panel to a second side of the circuit board.

In accordance with one embodiment, the clip includes a first arm portion configured to apply pressure to a first panel in order to force the first panel against a first contact surface on a first side of a second panel, e.g., a circuit board, and a second arm portion configured to apply pressure to a third panel in order to force the third panel against a second contact surface on a second side of the second panel. The clip further includes a bridge portion connecting the first and the second arm portions, the bridge portion having a central section configured to provide a mechanical coupling with an edge of the third panel.

In accordance with a further embodiment, an assembly includes a first panel, a second panel, e.g., a circuit board, and a third panel. The first panel is arranged at a first side of the second panel and the third panel is arranged at a second side of the second panel. The assembly further includes a clip attaching the first and the third panels to the second panel. The clip itself includes a first arm portion, a second arm portion and a bridge portion. The first arm portion applies pressure to the first panel in order to force the first panel against a first contact surface on the first side of the second panel. The second arm portion applies pressure to the third panel in order to force the third panel against a second contact surface on the second side of the second panel. The bridge portion connecting the first and the second arm portions includes a central section. The central section provides a mechanical coupling to an edge of the second panel.

Embodiments relating to a clip for attaching panels to each other as well as embodiments relating to an assembly including such a clip are explained in conjunction with the drawings.

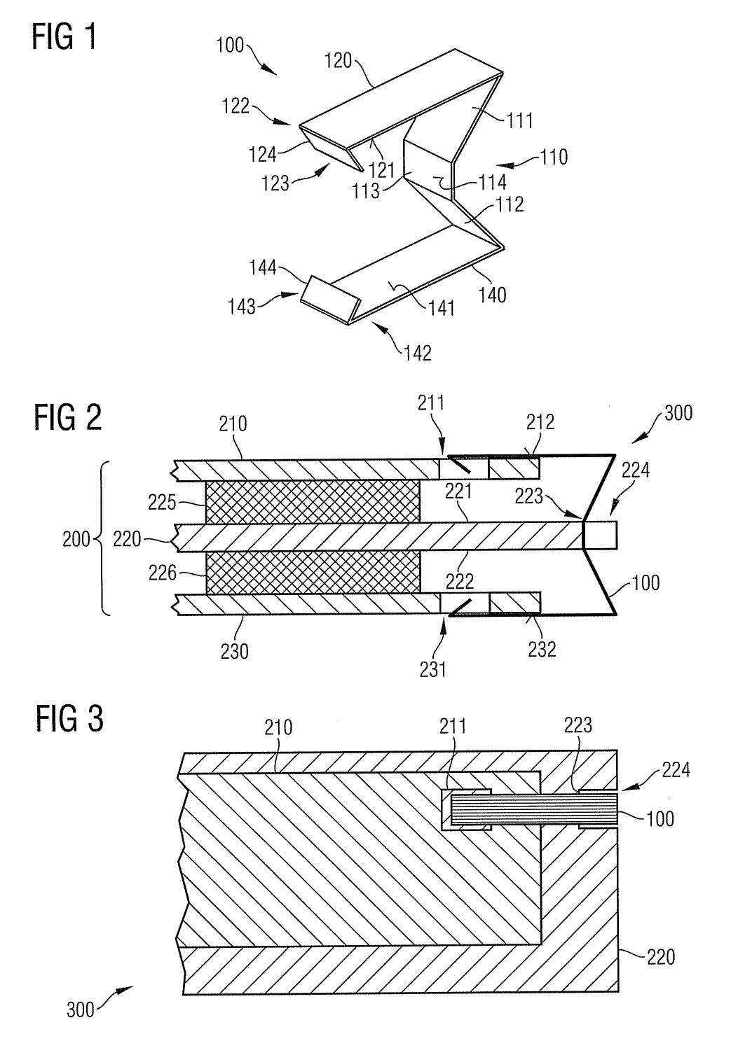

Referring now to FIGS. 1 and 2, an embodiment of the clip 100 for attaching panels is illustrated. The clip 100 includes a first arm portion 120, a second arm portion 140 and a bridge portion 110 connecting the two arm portions 120, 140. The arm portions 120, 140 are formed as elongated, here planar and horizontal extensions projecting from folds at the distal ends of the bridge portion 110. They may be arranged substantially in parallel to each other in order to facilitate the mounting of the clip 100. In order to hold panels 210, 220, 230 forming a stack 200 together, each arm portion 120, 140 is configured to apply pressure to a pressure receiving outer surface 212, 232 of an outer panel 210, 230 of the stack 200.

The bridge portion 110 connecting the two arm portions 120, 140 includes a central section 113 and two spring sections 111, 112. Each spring section 111, 112 connects the central section 113 with one of the arm portions 120, 140. The central section 113 is configured to provide a mechanical coupling to an edge 223 of the second panel 220. In order to provide an adequate contact to a corresponding surface of the edge 223 of the circuit board 220, the central section 113 may include a special formed contact surface 114, e.g., a substantially plane contact surface.

The bridge portion 110 may be provided with an impressed or concave shape. This may be achieved by inwardly bending the two spring sections 111, 112. An exemplary clip 100 including a bridge portion 110 with an impressed shape is illustrated in FIG. 1. The two substantially plane spring sections 111, 112 are inclined towards the region between the two arm portions 120, 140. It should be noted that the impressed shape of the bridge portion 110 may equally be achieved with rounded or curved spring sections (not shown herein), as well. As a result of the impressed shape of the bridge portion 110, the central section 113 is displaced towards the region between the two arm portions 120, 140. Therefore, the clip of FIG. 1 has a sigma-shaped body.

The body of the clip 100 may be at least partially formed from a resilient material such as metal. It should be noted that different materials, e.g., plastic materials, or combinations of such materials may be used for the clip 100. In one embodiment the body of the clip 100 is formed as a metal strip formed from e.g., stainless steel or spring steel. Spring steel may be used if good spring characteristics are desired.

In one embodiment the two arm portions 120, 140 and the bridge portion 110 are integrally formed from a single material, e.g., sheet metal. Alternatively, a bended wire with a circular or any other suitable profile may be used for the clip 100.

At least one of the arm portions may include a locking member 123, 143 in order to lock the clip 100 in its mounted position. The locking member 123, 143 may provide a closure between the clip 100 and the stack 200, e.g., positive locking or friction locking. In order to provide a locking mechanism, the locking member 123, 143 may be configured to interact with a complementary locking member 211, 231 formed on the corresponding pressure receiving surface 211, 231 of the stack 200. A locking mechanism providing positive locking is illustrated e.g., in FIG. 2.

The locking member 123, 143 may be formed as a protrusion 124, 144 projecting inwardly towards the region between the two arm portions 120, 140. It may then be configured to engage into a corresponding recess 211, 231 of the pressure receiving surface 212, 232 of the associated panel 210, 230. In another embodiment, the locking member 123, 143 may be formed as a recess in the pressure applying surface 121, 141 of the arm portion 120, 140 configured to receive the complementary locking member 221, 231 formed as a protrusion projecting from the pressure receiving surface 212, 232 of the associated panel 210, 230. The locking member 123, 143 of the arm portion 120, 140 may be formed as a bent edge, a barb, a nose, a hook or any equivalent protrusion.

The clip 100 illustrated in FIG. 1 includes two locking members 123, 143 formed as protrusions 124, 144 arranged in an end region 122, 142 of the corresponding arm portion 120, 140. Each locking member 123, 143 is formed as a bent edge. The bent edge 124, 144 may project from the arm portion 120, 140 with an angle of substantially 90 degrees. In order to facilitate the mounting of the clip 100, the bent edge 124, 144 may be formed with an angle of less than 90 degrees. Here the bent edge is formed with an acute angle.

Referring now to FIG. 2, an embodiment of an assembly 300 is illustrated. The assembly 300 includes a first panel 210, an intermediate second panel 220 and a third panel 230. The first and the third panel 210, 230 are attached to the second panel 220 in order to form a stack 200. The stack 200 is held together by the clip 100 of FIG. 1. The intermediate panel 220 may be formed as a double sided circuit board. Each side 221, 222 of the double sided circuit board 220 may be populated with at least one electronic component 225, 226. Here, only one electronic component 225, 226 on each side 221, 222 of the circuit board 220 is illustrated. The two outer panels 210, 230 may be formed as heat dissipating panels such as heat spreaders (not shown herein). In order to provide a sufficient dissipation of the heat generated by the electronic components 225, 226, the first panel 210 is directly attached to a contact surface of the first electronic component 225 mounted on the first side 221 of the circuit board 220, whereas the third panel 230 is directly attached to a contact surface of the second electronic component 226 mounted on the second side 222 of the circuit board 220.

The clip 100 is locked in its mounted position by the two locking members 123, 143 arranged at the inner side of the arm portions 120, 140. Each of the locking members 123, 143 engages a complementary locking member 211, 231 formed as a recess in the pressure receiving surface 212, 232 of the associated outer panel 210, 230. Here, each recess 211, 231 is formed as an aperture in a border area of the corresponding heat dissipating panel 210, 230. It should be noted that the recess 211, 231 does not necessarily need to be formed as an aperture. Depending on the thickness of the outer panel 210, 230 and the design of the locking member 123, 143, the recesses 211, 231 may also be formed as blind holes.

The central section 113 of the bridge portion 110 engages a recess 224 at the edge of the circuit board 220 in order to provide a mechanical coupling to the circuit board 220. Here, the recess 224 is formed as an end notch in the circuit board 220. During mounting when the clip 100 is slid onto the stack 200, the central section 110 may fit into the end notch 224 and then the protrusions 124, 144 may hook into the holes 211, 231 of the heat dissipating panels 210 230. The mechanical coupling between the central section 113 and the circuit board 220 may prevent lateral movement of the outer panels 210, 230. The engaging of the central section 113 and the end notch 224 of the circuit board 220 becomes clearer in conjunction with FIG. 3.

It should be noted that the tension between the edge of the second panel 220 and the outer panels 210, 230 results in lateral tractive or tensile forces affecting the panels 210, 230. These tensile forces may be easily adapted to suit different applications and requirements by modifying the geometry of the clip and the panels, especially the length of the arm portions 120, 140, the position of the locking members 123, 143 along the arm portions, the position of the complementary locking members 211, 231 along the outer panels 210, 240 and the positions of the central section 113 and the contact surface 223 at the edge of the second panel 220. Also the pressure applied by the arm portions 120, 140 forcing the outer panels 210, 230 against a pressure receiving surface 212, 232 of the intermediate panel 220 may be adapted modifying the geometry and the materials of the clip 100 and the panels 210, 220, 230. In this context it should be noted that the bridge portion 110 may be designed as a brace providing a relatively high lateral tensile force to each outer panel 210, 230. In particular, the bridge portion 110 may be configured in such a way that the panels 210, 220, 230 are substantially held in position by an equilibrium of lateral tensile forces of at least two clips attached at opposite sides of the stack 200, provided that the tensile forces exceed the orthogonal compression forces of the arm portions 120, 140 by a multiple.

Referring now to FIG. 3, a side view of the assembly 300 of FIG. 2 is illustrated. The dimensions of the end notch 224 may be adapted to the dimensions of the clip 100. Here the proportions of the end notch 224 and the clip 100 are chosen in order to arrange the clip 100 completely within the lateral span of the second panel 220.

It is to be noted that a clip like that one illustrated in FIGS. 2 and 3 may also be used in conjunction with additional clips, e.g., such as on the top edge of the module.

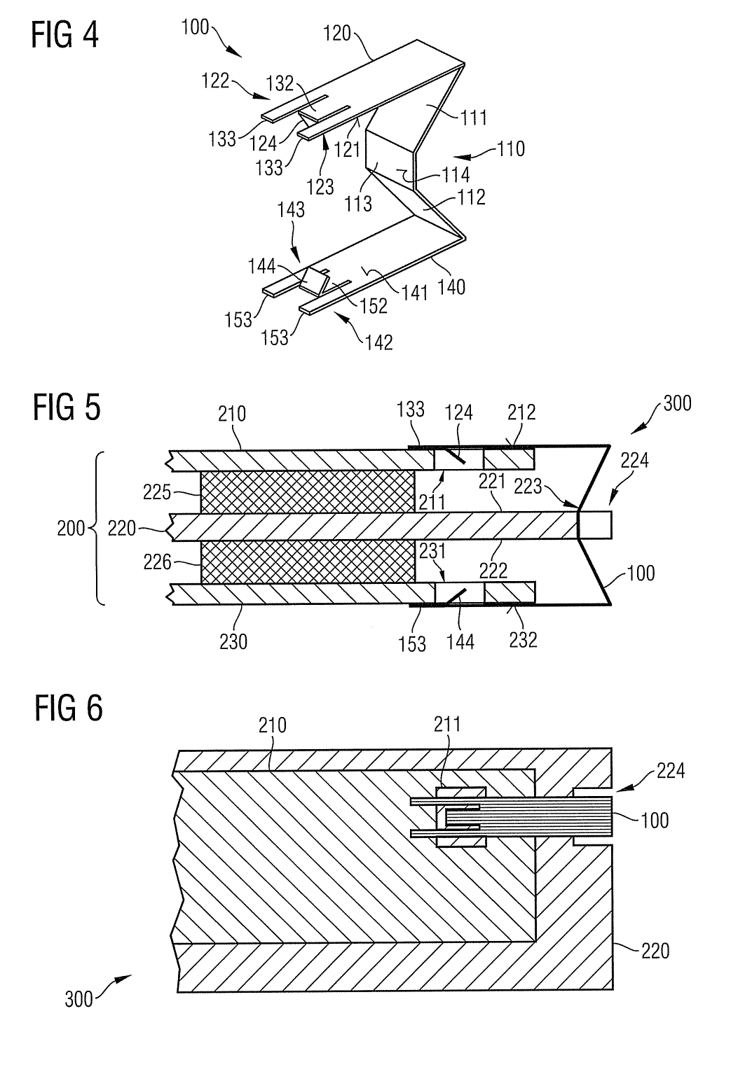

Referring now to FIG. 4, another embodiment of the clip 100 is illustrated. The clip 100 is substantially formed analogously to that one illustrated in FIG. 1. In order to provide a larger pressure applying surface 121, 141, only a middle part 132, 152 of the end section 122, 142 of the arm portion 120, 140 may be bent. Here the end section 122, 142 is formed by three fingers 132, 133, 152, 153, wherein only the middle finger 132, 152 is bent in order to form the locking member 123, 143.

Referring now to FIG. 5, an assembly 300 including the clip 100 of FIG. 4 is illustrated. In the mounted position of the clip 100 the bent middle fingers 124, 144 of the two arm portions 120, 140 engage the recesses 211, 231 formed in the pressure receiving surfaces 212, 232 of the corresponding panels 210, 230 and the outer fingers 133, 153 of the two arm portions 120, 140 apply pressure to the pressure receiving surface 212, 232 of the corresponding panels 210, 230.

Referring now to FIG. 6, a side view of the assembly of FIG. 5 is illustrated. Again the outer fingers of an arm portion, e.g., the first arm portion 120 apply pressure to the corresponding panel 210 and the bent middle finger secures the clip 100 in its position. The pressure applied to a panel 210, 230 depends on the spring properties of the corresponding arm portion 120, 140. Therefore the pressure may depend on the length of the corresponding arm portion 120, 140. In the embodiment illustrated in FIG. 6, the length of the outer fingers 133, 153 may also determine the pressure applied to the panels 210, 220.

In the mounted position of the clip 100 the impressed bridge portion 110 may act as a leaf spring.

To ensure an adequate fixing of the outer panels 210, 230 relatively to the intermediate panel 220 and an adequate contact between the outer panels 210, 230 and the integrated circuit devices 225, 226 respectively, the amount of pressure applied on the outer panels 210, 230 can easily be varied by the span width or the resilient properties of the clip 100. To facilitate the assembling of the clip 100, its span width can be configured to correspond approximately to the thickness of the stack 200 containing the panels 210, 220, 230. Anyway, due to its flexibility the clip 100 can easily correspond to different thicknesses of the stack 200. Apart from the specific design of the clip 100, the amount of pressure applied on the outer panels 210, 230 acting for example as heat dissipating elements can also be adjusted by varying other features of the clip 100 body such as its cross section or the material used for it.

As illustrated above, the locking members 123, 143 of the arm portions 120, 140 can be formed as latching elements configured to snap into corresponding recesses 211, 231 of the outer panels 210, 230. Alternatively, it is also possible to form the latching element on a heat dissipating panel 210, 230 and the corresponding recess within the associated arm portion 120, 140.

At least one of the following, the bridge portion 110 or the arm portions 120, 140 may be formed resiliently in order to facilitate the mounting of the clip 100 on the stack 200. Also the locking members 123, 143 may be formed resiliently in order to facilitate the mounting of the clip 100 on the stack 200.

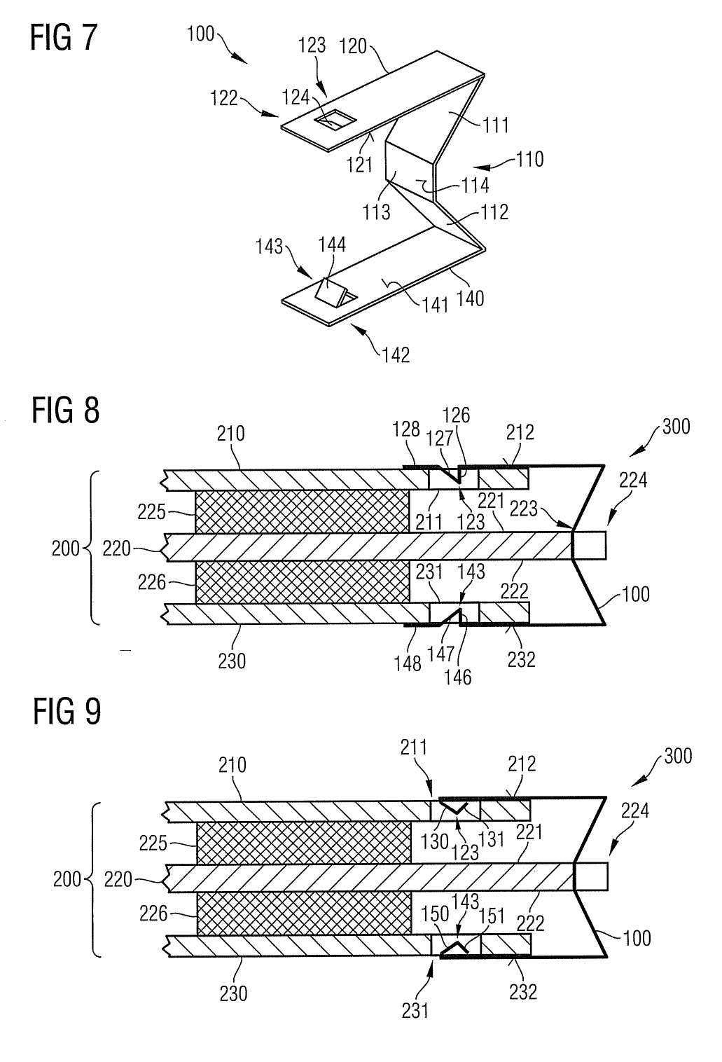

Referring now to FIG. 7, a further embodiment of the clip 100 is illustrated. Analog to the clips illustrated in FIGS. 1 and 4, the clip 100 has a sigma-shaped body with two arm portions 120, 140 and a bridge portion 110 connecting the arm portions. Each arm portion 120, 140 includes a locking member 123, 143 formed as a protrusion 124, 144 configured to engage a recess 211, 231 in a corresponding contact surface of the stack 200. The protrusion 124, 144 may be implemented as a barb formed for example as an inwardly bent region of the end section 122, 142 of the respective arm portion 120, 140. The barb 124, 144 may be formed compressible in order to facilitate the mounting of the clip 100.

Referring now to FIGS. 8 and 9, two examples of an assembly 300 are illustrated. The assembly 300 includes a stack 200 of a first, a second and a third panel 210, 220, 230, the panels 210, 220, 230 being held together by sigma-shaped clips 110 according to further embodiments. Each arm portion 120, 140 of the sigma-shaped clip 100 includes a locking member 123, 143 configured to engage a recess 211, 231 in a corresponding contact surface 212, 232 of the stack 200. The locking member 123, 143 is formed as a protrusion at the distal end of the respective arm portion 120, 140. In FIG. 8 the protrusion is implemented as a shoulder section 126, 146 projecting inwardly towards the region between the two arm portions 120, 140. The shoulder section 126, 146 is formed, at one end thereof, from a fold formed in the distal end region of the arm portion 120, 140.

The shoulder section 126, 146 may terminate at the other end thereof into a sloping section 127, 147 which facilitates the mounting of the clip 100. The sloping section 127, 147 itself may terminate into a horizontal end section 128, 148 of the arm portion 120, 140. The horizontal end section 128, 148 may be formed to apply pressure to the corresponding contact surface 212, 232 of the stack 200. In FIG. 9 the protrusion is implemented as an inwardly bent end section of the respective arm portion 120, 140. The bent end section may be formed as a loop 129, 149 including a first and a second loop section 130, 131, 150, 151. As illustrated in FIG. 9, the first loop section 129, 149 is formed from a fold at the very distal end region 122, 142 of the arm portion 120, 140 and may facilitate the mounting of the clip 100 onto the stack 200. It terminates into the second loop section 131, 151.

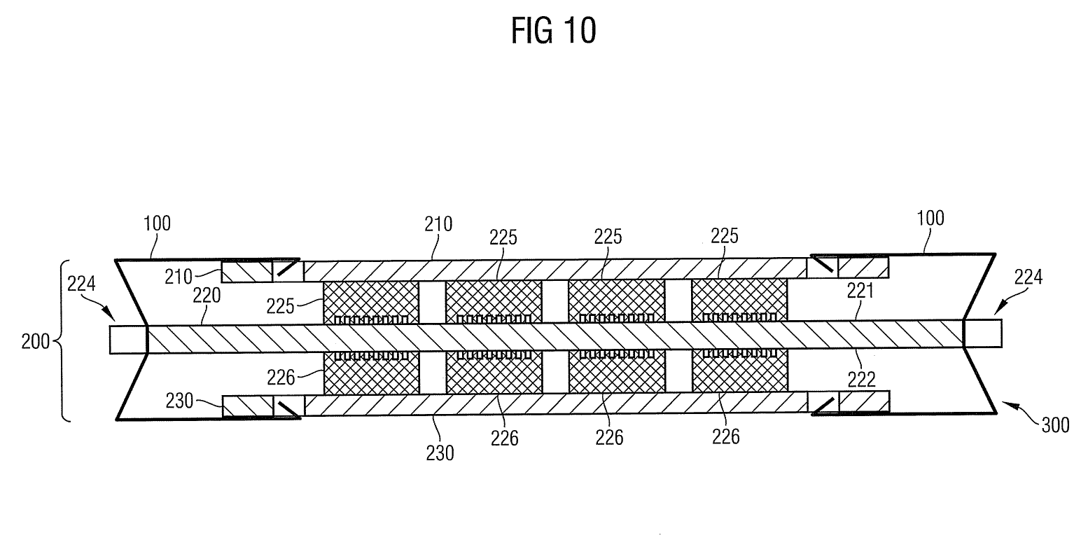

Referring now to FIG. 10, an embodiment of a circuit board assembly 300 is illustrated. The assembly 300 includes a stack 200 formed by a first panel 210, a second panel 220 formed as a circuit board and a third panel 230. The three panels are held together by two clips 110 of FIG. 1. These clips 110 which for example are arranged at opposite edges of the intermediate second panel 220 apply tension between the edges of the second panel 220 and the two outer panels 210, 230 in order to hold the two outer panels 210, 230 in position and provide mechanical coupling to the second panel 220. The tensile forces applied to the outer panels 210, 230 by the two clips 110 arranged at opposite sides of the stack 200 typically result in a tensile stress acting on the outer panels 210, 230. In the case that the bridge portions of the clips 110 are designed as braces, the tensile forces applied to the outer panels 210, 230 may exceed the orthogonal compression forces of the arm portions 120, 140 by a multiple. Then the position of the outer panels 210, 230 relative to the second panel 220 may be determined predominantly by the equilibrium of the lateral tensile forces. Nevertheless, the correct position of the outer panels 210, 230 on the module 220 may also be adjusted by the position and geometry of the corresponding end notches 224. The second panel 220 is formed as a double sided circuit board. Each side 221, 222 of the double sided circuit board 220 is populated with a set of four electronic components 225, 226. The allocation of the electronic components 225, 226 to the circuit board 220 is exemplarily indicated by eight leads per electronic component 225, 226, the leads being arranged on that side of an electronic component 225, 226 which faces the circuit board 220. The two outer panels 210, 230 are attached directly to the electronic components 225, 226. They may be formed as heat dissipating panels in order to dissipate the heat generated by the electronic components 225, 226 of the circuit board 220.

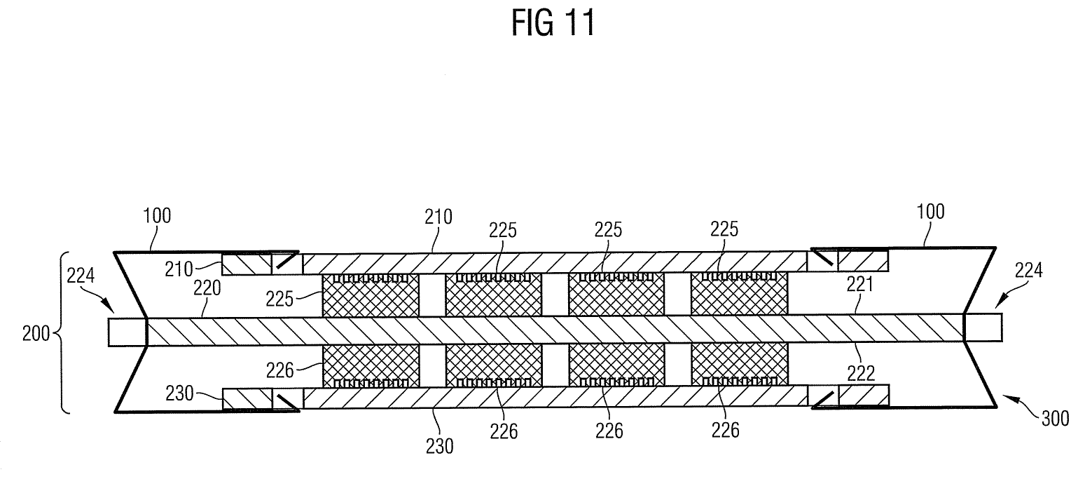

Referring now to FIG. 11, another embodiment of a circuit board assembly 300 is illustrated. Analogously to FIG. 10 the assembly 300 includes a stack 200 formed by a first panel 210, an intermediate second panel 220 and a third panel 230 which are held together by two clips 100 of FIG. 1. In contrast to the embodiment illustrated in FIG. 10, the two outer panels 210, 230 are formed as circuit boards. Each circuit board 210, 230 is populated with a set of four electronic components 255, 256 arranged on the inner side of the specific circuit board 210, 230. This is exemplarily indicated by eight leads per electronic component 255, 256, the leads being arranged on that side of a electronic component 255, 256 which faces the corresponding circuit board 210, 230. The two circuit boards 210, 230 are attached to the intermediate panel 220 with the aid of two clips 100. The central second panel 220 may be formed as a heat dissipating panel in order to dissipate the heat generated by the electronic components 225, 226 of both circuit boards 210, 230. Each of the circuit boards 210, 230 may be formed as a double sided circuit board including at least one electronic component mounted on the outer side of the specific circuit board (not shown herein).

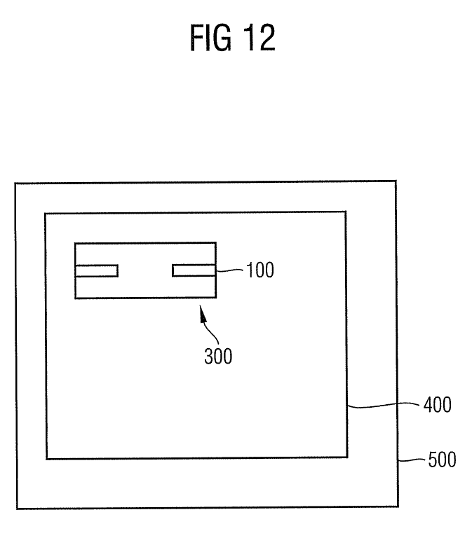

Referring now to FIG. 12, a computer device 500 including at least one assembly 300 is illustrated. The assembly 300 may be formed as a circuit board assembly according to one of the embodiments illustrated in FIGS. 10 and 11. The circuit board assembly 300 may be formed as a double inline memory module (DIMM) including a double-sided circuit board with a set of integrated memory devices mounted on each side of the board and two panels, for example two heat dissipating panels, attached to the circuit board. The two panels are secured in their position by at least one clip 100. The circuit board assembly 300 may be arranged on a main board 400 of the computer device 500. The computer device 500 may also include further assemblies (not shown herein). These assemblies may for example include single- or double-sided circuit boards populated with memory or any other electronic components as well as other panels attached to the circuit boards by using one or more clips.

As illustrated above, the attachment of panels to a circuit board may be applied in a number of different applications. It is to be noted, however, that the accompanying drawings illustrating flat panels attached directly to one or more electronic components in order to dissipate heat generated by the electronic components are not to be considered limiting of the scope of the invention.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A clip for attaching both a first panel to a first side of a second panel and a third panel to a second side of the second panel, the clip comprising:
a first arm portion configured to apply pressure to the first panel in order to force the first panel against a first contact surface on the first side of the second panel;
a second arm portion configured to apply pressure to the third panel in order to force the third panel against a second contact surface on the second side of the second panel; and
a bridge portion connecting the first and the second arm portions, the bridge portion comprising a central section configured to provide a mechanical coupling with an edge of the second panel.

2. The clip of claim 1, wherein the bridge portion has an impressed shape.

3. The clip of claim 2, wherein the bridge portion comprises a substantially plane central section and two spring sections each connecting the central section with one of the arm portions.

4. The clip of claim 3, wherein the clip has a substantially sigma-shaped body with substantially plane spring sections inclined relatively to the plane central section.

5. The clip of claim 4, wherein at least one of the arm portions comprises a locking member configured to interact with a complementary locking member of the associated first or third panel in order to lock the clip in its mounted position.

6. The clip of claim 5, wherein the locking member comprises a protrusion configured to engage a recess of the complementary locking member of the associated panel.

7. The clip of claim 6, wherein the protrusion is formed as an inwardly bent part of the arm portion.

8. The clip of claim 5, wherein the locking member comprises a recess formed in the contact surface of the arm portion, the recess being configured to receive a protrusion of the complementary locking member of the associated panel.

9. The clip of claim 1, wherein at least a part of the clip is made of a resilient material, such as metal.

10. The clip of claim 9, wherein at least a part of the clip is made of a metal strip.

11. The clip of claim 1, wherein the clip is configured to hold together a stack comprising a first, a second and a third panel, wherein at least one of the panels is formed as a circuit board populated with at least one electronic component, and wherein the clip is formed to apply pressure to the stack in order to force a surface of the electronic component against an adjacent panel.

12. The clip of claim 1, wherein the clip is configured to hold together a stack comprising a first, a second and a third panel, wherein at least one of the panels is formed as a circuit board populated with at least one electronic component, and wherein the bridge portion is formed as a brace in order to apply tensile forces to the first and the third panel.

13. An assembly comprising:
a first panel, a second panel and a third panel, the first panel being arranged at a first side of the second panel and a third panel being arranged at a second side of the second panel;
a clip attaching the first and the third panel to the second panel, the clip comprising:
a first arm portion applying pressure to the first panel in order to force the first panel against a first contact surface on the first side of the second panel;
a second arm portion applying pressure to the third panel in order to force the third panel against a second contact surface on the second side of the second panel; and
a bridge portion connecting the first and the second arm portions, wherein the bridge portion comprises a central section providing a mechanical coupling to an edge of the circuit board.

14. The assembly of claim 13, wherein the central section engages a corresponding recess at the edge of the circuit board.

15. The assembly of claim 13, wherein the bridge portion has an impressed shape.

16. The assembly of claim 15, wherein the bridge portion comprises a substantially plane central section and two spring sections each connecting the central section with one of the arm portions.

17. The assembly of claim 16, wherein the clip has a substantially sigma-shaped body with substantially plane spring sections inclined relatively to the plane central section.

18. The assembly of claim 13, wherein at least one of the panels is formed as a circuit board.

19. The assembly of claim 18, wherein at least one side of the circuit board is populated with at least one electronic component, and wherein the pressure of the clip forces the electronic component against an adjacent panel.

20. The assembly of claim 19, wherein at least one of the electronic elements is an integrated memory device.

21. The assembly of claim 20, wherein the circuit board is formed as a double-inline-memory-module.

22. The assembly of claim 13, wherein the first and the third panels are attached to the second panel by at least two clips, the two clips being arranged at different edges of the second panel.

23. The assembly of claim 22, wherein the bridge portions of the clips are designed as braces providing lateral tensile forces to the panels, and wherein the panels are held in position by an equilibrium of the lateral tensile forces of the clips.
